(19) United States
(12) Patent Application Publication
(10) Pub. No.: US 2013/0252428 A1
(43) Pub. Date: Sep. 26, 2013

(54) Photo-etching and Exposing System

(71) Applicant: Wen Da Cheng, Shenzhen (CN)

(72) Inventor: Wen Da Cheng, Shenzhen (CN)

(73) Assignee: Shenzhen China Star Optoelectronics Technology Co. LTD., Shenzhen (CN)

(21) Appl. No.: 13/512,340

(22) PCT Filed: Apr. 13, 2012
(86) PCT No.: PCT/CN12/73975

§ 371 Date: May 28, 2012

(30) Foreign Application Priority Data
Mar. 26, 2012 (CN) 201210082947.2

(51) Int. Cl. H01L 21/311; G03B 27/42

(52) U.S. Cl. 438/694; 355/53; 257/E21.249

(57) ABSTRACT

A method of photo-etching is proposed. The method includes steps as follows. Expose a photoresist layer with a stack of at least two masks. Each mask defines a corresponding pattern, and a new pattern is formed when the at least two masks are stacked. Process the exposed photoresist layer to derive a hollow-out structure that complements the new pattern. A mask system is also proposed. The adoption of the abovementioned method can lower the possibility of manufacturing new masks and reduce production costs.

### BACKGROUND OF THE INVENTION

1. Field of the Invention

The present invention relates to a semiconductor technology, and more particularly, to a system of photo-etching and exposing.

2. Description of the Prior Art

Photo-etching is a technique capable of forming precision, tiny and complex patterns on a thin film surface or a metal plate. Photo-etching is an important manufacturing technique, especially in the semiconductor production industry. Photo-etching process (PEP) is a complicated process, and exposure is the most important step in the process. Exposure requires a mask, light source and substrate.

As one of the production methods of semiconductor, photo-etching is a pattern transferring process with multiple steps. The needed pattern is first formed on the mask, and then PER is used to etch the needed pattern on to every layer of a wafer surface. In practice, the process begins with the pattern transferred to the photoresist layer. Once exposed, the photoresist layer changes its nature and composition, e.g., from soluble to insoluble, or vise versa. Then some chemical solvent is used to dissolve the soluble parts, leaving a hollow-out structure complementary to the pattern on the mask. At this point, the pattern on the mask is transferred to the photoresist layer. The next step is to transfer the pattern from the photoresist layer to wafers. The transfer is mainly done with various engraving methods to remove the membrane on the wafer that is not protected by the photoresist layer. After the removal, the pattern transfer is complete.

In the existing semiconductor production process, usually a single mask can only be used for one exposure because the pattern is different in every exposure. However, even if the pattern in the next exposure is the same as the previous pattern with more or less details, a new mask must be used or manufactured. The abovementioned scenario is not only time-consuming but also significantly raises production costs.

### SUMMARY OF THE INVENTION

An object of the present invention is to provide a method of photo-etching and an exposing system for lowering the possibility of manufacturing new masks and reducing production costs.

According to the present invention, a method of photo-etching comprises: forming a material layer on a substrate; forming a photoresist layer on the material layer; exposing the photoresist layer by using a stack of at least two masks, each mask defining a corresponding pattern, a new pattern being defined when the at least two masks are stacked, wherein at least one line of the corresponding pattern from one of the at least two masks is located in the middle of two adjacent lines of another corresponding pattern from another mask in the new pattern; processing the exposed photoresist layer to derive a hollow-out structure that complements the new pattern; etching the material layer by using the hollow-out structure to form a patterned material layer; removing the photoresist layer of the hollow-out structure after forming the patterned material layer.

In one aspect of the present invention, the corresponding patterns are stacked and form a mask set defining a new pattern, the mask set comprises a primary mask and a supplementary mask, and at least two mask sets comprise the same primary mask and different supplementary masks.

In another aspect of the present invention, at least one line of the corresponding pattern from one of the at least two masks is located in the middle of two adjacent lines of another corresponding pattern from another mask in the new pattern.

In still another aspect of the present invention, each line of the corresponding pattern from one of the at least two masks is located in the middle of two adjacent lines of another corresponding pattern from another mask in the new pattern.

According to the present invention, a method of photo-etching comprises: forming a material layer on a substrate; forming a photoresist layer on the material layer; exposing the photoresist layer by using a stack of at least two masks, each mask defining a corresponding pattern, a new pattern being defined when the at least two masks are stacked; processing the exposed photoresist layer to derive a hollow-out structure that complements the new pattern; etching the material layer by using the hollow-out structure to form a patterned material layer.

In one aspect of the present invention, the corresponding patterns are stacked and form a mask set defining a new pattern, the mask set comprises a primary mask and a supplementary mask, and at least two mask sets comprise the same primary mask and different supplementary masks.

In another aspect of the present invention, at least one line of the corresponding pattern from one of the at least two masks is located between two adjacent lines of another corresponding pattern from another mask in the new pattern.

In another aspect of the present invention, at least one line of the corresponding pattern from one of the at least two masks is located in the middle of two adjacent lines of another corresponding pattern from another mask in the new pattern.

In yet another aspect of the present invention, each line of the corresponding pattern from one of the at least two masks is located in the middle of two adjacent lines of another corresponding pattern from another mask in the new pattern.

In still another aspect of the present invention, the method further comprises removing the photoresist layer of the hollow-out structure after forming the patterned material layer.

According to the present invention, an exposing system comprises a light source; a first mask, defining a first pattern; a second mask, defining a second pattern; wherein the first mask and the second mask are stacked, the stack of the first pattern and the second pattern forms a third pattern, and light emitted by the light source crosses the third pattern.

In one aspect of the present invention, the third pattern is a semiconductor pattern for forming an array substrate of a liquid crystal display (LCD) panel.

In another aspect of the present invention, the corresponding patterns are stacked and form a mask set defining a new pattern, the mask set comprises a primary mask and a supplementary mask, and at least two mask sets comprise the same primary mask and different supplementary masks.

In another aspect of the present invention, at least one line of the corresponding pattern from one of the at least two masks is located between two adjacent lines of another corresponding pattern from another mask in the new pattern.

In still another aspect of the present invention, at least one line of the corresponding pattern from one of the at least two masks is located in the middle of two adjacent lines of another corresponding pattern from another mask in the new pattern.

In yet another aspect of the present invention, each line of the corresponding pattern from one of the at least two masks is located in the middle of two adjacent lines of another corresponding pattern from another mask in the new pattern.

Contrast to the conventional technology that only a mask is exposed, the present invention adopts the method of exposing a stack of masks. An advantage of the present invention is that, it is unnecessary to manufacture a new mask defining a complete pattern when the new mask defines a pattern with more or less details than an original mask does. Thus, the method provided by the present invention can lower the possibility of manufacturing new masks and can reduce production costs.

### BRIEF DESCRIPTION OF THE DRAWINGS

FIG. 1 illustrates a flowchart of a method of photo-etching according to a preferred embodiment of the present invention.

FIG. 2 illustrates a three-dimensional diagram of a primary mask in the method of photo-etching according to another preferred embodiment of the present invention.

FIG. 3 illustrating a three-dimensional diagram of a supplementary mask in the method of photo-etching according to another preferred embodiment of the present invention.

FIG. 4 shows a three-dimensional diagram of a stack of the primary mask 20 and the supplementary mask.

FIG. 5 illustrates an equivalent diagram of the stack of the primary mask and the supplementary mask.

FIG. 6 illustrates a three-dimensional diagram of a stack of masks in the method of photo-etching according to another preferred embodiment of the present invention.

FIG. 7 illustrates an equivalent diagram of the stack of masks shown in FIG. 6.

### DETAILED DESCRIPTION OF THE PREFERRED EMBODIMENTS

The following is a detailed description of the preferred embodiment of the invention.

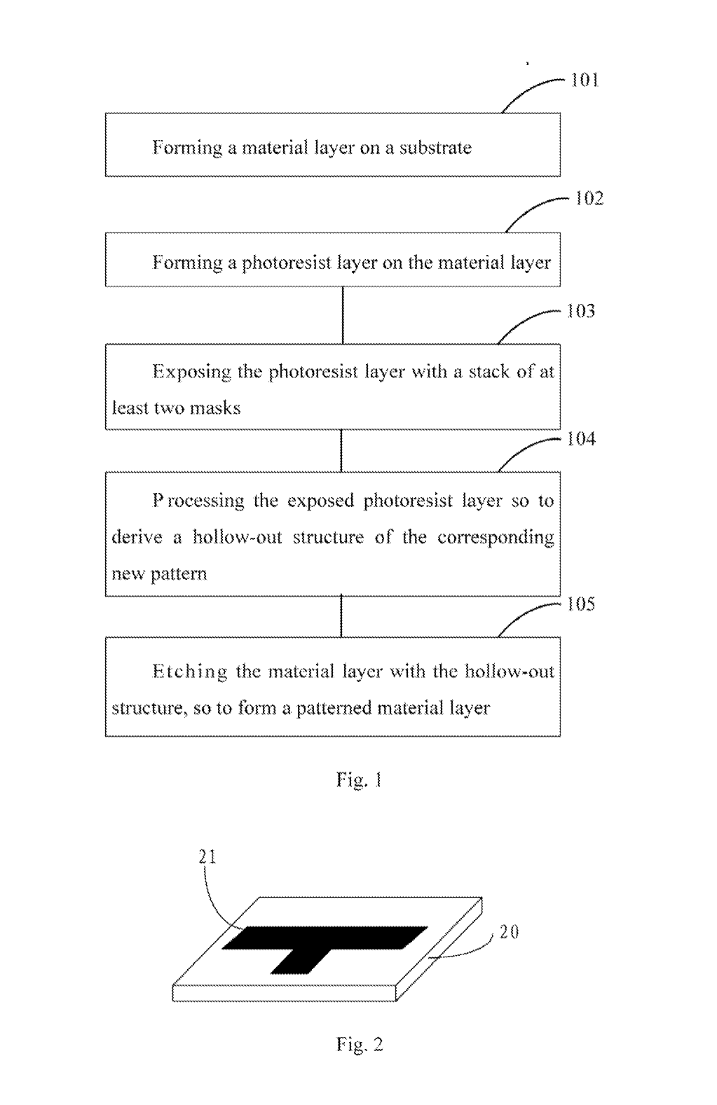

Please refer to FIG. 1 illustrating a flowchart of a method of photo-etching according to a preferred embodiment of the present invention. The method comprises the following steps of:

Step 101: forming a material layer on a substrate;

Photo-etching technology is most frequently used in the production of compound semiconductors. It is extensively applied in the production of plane devices and integrate circuits (ICs). For example, multiple photo-etching processes are needed in the production of planar transistors and ICs to attain to selective diffusion and metal film wiring.

The substrate is a wafer which the silicon chip used in the production of silicon semiconductor ICs.

The material layer comprises mediums including metal layers, polysilicon layers or amorphous silicon layers.

Step 102: forming a photoresist layer on the material layer;

Photo-etching generally starts with transferring patterns on a mask to the photoresist layer on the surface of the substrate, followed by etching or ion implantation. Therefore, it is necessary to form a photoresist layer on the material layer, so the material layer could be etched later.

Step 103: exposing the photoresist layer with a stack of at least two masks; Each mask defines a corresponding pattern, and a new pattern is formed when the at least two masks are stacked;

By exposure, the patterns on the masks can be transferred to the material layer, forming a new pattern on the material layer.

In the present invention, when the pattern needed for a specific exposure is the same as that on existing masks except a few details, and some other existing masks already carries these extra details, then the needed pattern could be formed by stacking multiple existing masks, with which the exposure could be done. “Multiple” refers to two or more masks.

The light source of the exposure could be an electron beam, ion beam. X-ray or ultraviolet ray.

What is worthy of noting is that during the exposure process, the mask and the substrate have to be accurately located for projection, to ensure the precision of patterns formed on the substrate.

Step 104: processing the exposed photoresist layer so to derive a hollow-out structure of the corresponding new pattern;

Due to the nature of photoresist, a choice could be make between saving the exposed or unexposed parts of the photoresist layer. Thus a hollow-out structure of the corresponding new pattern is derived. At this point, the pattern formed by the at least two stacked masks is transferred on to the photoresist layer.

Step 105: etching the material layer with the hollow-out structure, so to form a patterned material layer;

after the photo-etching in step 103, the new pattern formed by the at least two stacked masks has been transferred on to the photoresist layer. Then, the hollow-out structure of the photoresist layer can be used to etch the parts of the material layer that was not protected by the photoresis layer, so to form a patterned material layer. For example, in the production process of ICs, circuit patterns are transferred to the surface of the single crystal silicon or the medium, forming an effective pattern via or functional pattern.

After forming the needed patterned material layer, remove the photoresist layer of the hollow-out structure.

The following is a detailed description on mask stacking. The example is the stacking of two masks, as shown in FIGS. 2, 3, 4 and 5:

Please refer to FIG. 2 illustrating a three-dimensional diagram of a primary mask 20 in the method of photo-etching according to another preferred embodiment of the present invention. As shown in FIG. 2, a pattern on the primary mask 20 is a T-shaped pattern 21. If the pattern on the mask is determined by an opaque region, the mask is defined as a light-field mask. The primary mask 20 is defined as a light-field mask. The T-shaped pattern 21 is defined as an opaque region.

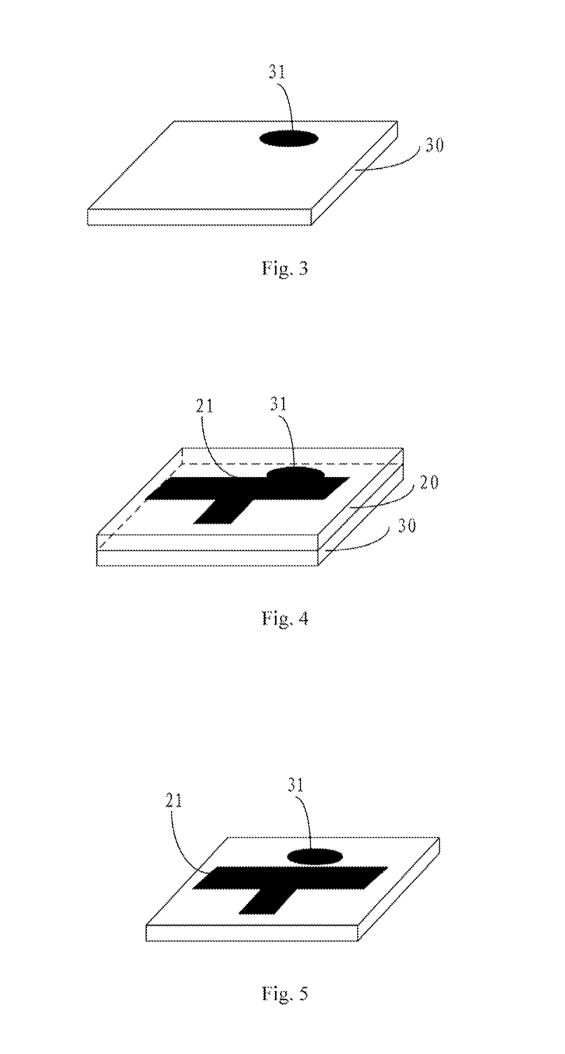

Please refer to FIG. 3 illustrating a three-dimensional diagram of a supplementary mask 30 in the method of photo-etching according to another preferred embodiment of the present invention. As shown in FIG. 3, a pattern on the supplementary mask 30 is a circular pattern 31. The supplementary mask 30 is defined as a light-field mask. The circular pattern 31 is defined as an opaque region.

FIG. 4 shows a three-dimensional diagram of a stack of the primary mask 20 and the supplementary mask 30.

Please refer to FIG. 5 illustrating an equivalent diagram of the stack of the primary mask 20 and the supplementary mask 30. A new pattern is formed after the primary mask 20 and the supplementary mask 30 are stacked. The new pattern looks like a combination of the T-shaped pattern 21 and the circular pattern 31 on the same mask.

As mentioned above, the corresponding patterns are stacked and form a mask set having a new pattern. The mask set comprises the primary mask 20 and the supplementary mask 30. The primary masks 20 on at least two mask sets are the same, and the supplementary masks 30 are different.

Further, the pattern on the primary mask 20 and the corresponding pattern on one (or more than one) supplementary mask(s) 30 are stacked to form a new pattern.

The abovementioned embodiment describes the situation that the pattern on a mask needed for a specific exposure is the same as that on the existing masks except more details. As for the situation that the pattern on a mask needed for a specific exposure is the same as that on the existing masks except less details, the following methods could be used:

The photoresist layer is still exposed by using the stack of the at least two masks. The stack of masks comprises the primary mask 20 and the supplementary mask 30. The pattern of the primary mask 20 comprises the pattern of the supplementary mask 30. The primary mask 20 is defined as a dark-field mask and the supplementary mask 30 is defined as a light-field mask. Expose the stack of the primary mask 20 and the supplementary mask 30. After the exposure, a pattern is formed on the material layer. The pattern on the material layer is the pattern on the primary mask 20 getting rid of the corresponding pattern on the supplementary mask 30.

Instead of manufacturing new masks, any desired pattern could be formed by flexibly combining the existing masks as the abovementioned method does.

Take a linear pattern on the mask for example. In a practical operation, the higher the accuracy is demanded, the smaller the distance between two adjacent lines is required. Correspondingly, it causes higher production costs. By adopting the method of stacking a plurality of masks, it is easier to realize high accuracy and to reduce the distance between two adjacent lines shown by the pattern formed on the material layer. In this way, there is no need to remanufacture highly accurate masks, which not only decreases production costs but also saves time.

If different masks are stacked, the stack of corresponding patterns forms a new pattern. At least one line of the corresponding pattern from a mask is located between two adjacent lines of another corresponding pattern from another mask in the new pattern. Specifically, at least one line of the corresponding pattern from a mask is located in the middle of two adjacent lines of another corresponding pattern from another mask in the new pattern. Or, each line of the corresponding pattern from a mask is located in the middle of two adjacent lines of another corresponding pattern from another mask in the new pattern. By exposing the new pattern, an object of using a mask defining a pattern of low accuracy to realize highly accurate exposure could be achieved.

The following is a detailed description on the stack of masks on which the pattern is straight lines.

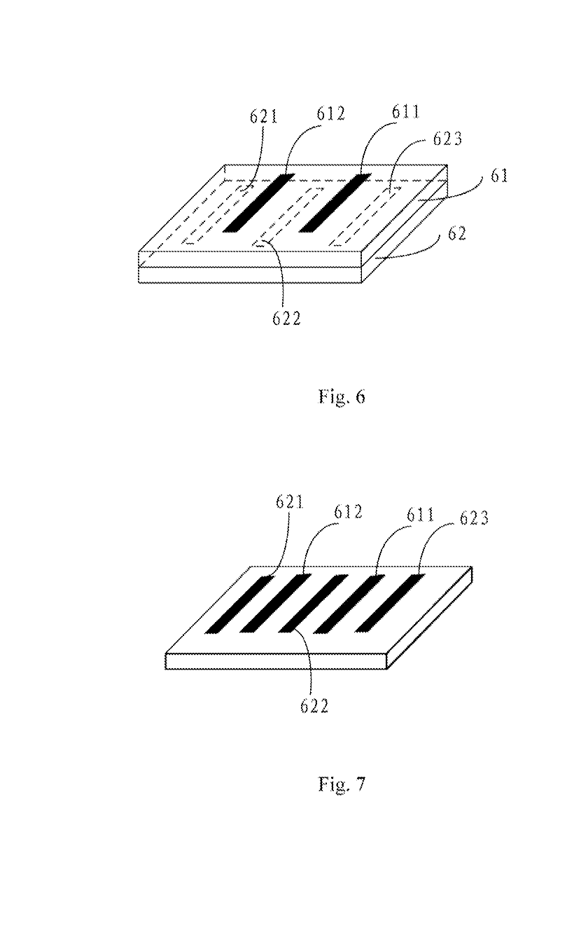

Please refer to FIG. 6 illustrating a three-dimensional diagram of a stack of masks in the method of photo-etching according to another preferred embodiment of the present invention. As shown in FIG. 6, the mask comprises a first mask 61 and a second mask 62. At least two straight lines, such as a straight line 611 and a straight line 612, are disposed in parallel on the first mask 61. The distance between the straight line 611 and the straight line 612 is defined as a first predetermined distance. At least two straight lines, such as a straight line 621, a straight line 622, and a straight line 623, are disposed in parallel on the second mask 62. The distance between the straight line 621 and the straight line 622 and between the straight line 622 and the straight line 623 is defined as a second predetermined distance. The linear pattern on the first mask 61 and the linear pattern on the second mask 62 are stacked in parallel to form a new pattern. The straight line 611 is disposed between the straight line 622 and the straight line 623. The straight line 612 is disposed between the straight line 621 and the straight line 622.

Please refer to FIG. 7 illustrating an equivalent diagram of the stack of masks shown in FIG. 6. A new pattern comprising straight lines is formed by the stack of masks. The distance of two adjacent straight lines on the new pattern is smaller than that of two adjacent straight lines on the first mask 61 or the on the second mask 62.

Further, it is allowable that only a straight line is disposed on either the first mask 61 or the second mask 62. But it is not allowed that only a straight line is simultaneously disposed on the first mask 61 and on the second mask 62.

The first predetermined distance could be the same as the second predetermined distance. It seems that two masks are stacked and the pattern on each of the masks has the same accuracy. That is, a new pattern is formed after the linear pattern on the first mask 61 and the linear pattern on the second mask 62 are stacked in parallel without being overlapped with each other. By using the abovementioned method, an object of using a mask defining a pattern of low accuracy to realize highly accurate exposure is achieved. Of course, it is allowable to stack three or more than three masks to obtain a pattern of higher accuracy.

To realize the method of photo-etching as shown in FIG. 1, a mask set is provided according to a preferred embodiment of the present invention. The following is a detailed description on the mask set as shown in FIG. 6. The mask set comprises the first mask 61, and the second mask 62. A first pattern, such as the pattern comprising the straight line 611 and the straight line 612, is disposed on the first mask 61. A second pattern, such as the pattern comprising the straight line 621, the straight line 622, and the straight line 623, is disposed on the second mask 62. When the first mask 61 and the second mask 62 are stacked, the first pattern and the second pattern are stacked as well to form a third pattern, such as the pattern shown in the equivalent diagram in FIG. 7. In the present embodiment, the third pattern is a semiconductor pattern on an array substrate in a liquid crystal display (LCD) panel. Of course, the third pattern could be a pattern during manufacturing processes of other products.

A mask defining a new pattern such as the first mask 61 and the second mask 62 is formed after the masks having the corresponding patterns are stacked. The mask is defined as a mask set. The mask set comprises a primary mask and a supplementary mask. For example, the first mask 61 is defined as the primary mask, and the second mask 62 is defined as the supplementary mask. In a plurality of mask sets, at least two mask sets have the same primary masks and have different supplementary masks for reducing the number of masks. Meanwhile, at least one line of the corresponding pattern from the primary mask is located between two adjacent lines of the corresponding pattern from the supplementary mask in the new pattern. In this way, an object of using a mask defining a pattern of low accuracy to realize highly accurate exposure is achieved.

To realize the method of photo-etching as shown in FIG. 1, an exposing system is also provided by the present invention. The following is a detailed description on the mask set shown in FIG. 6. The exposing system comprises the light source, the first mask 61, and the second mask 62. The first pattern, such as the pattern comprising the straight line 611 and the straight line 612, is disposed on the first mask 61. The second pattern, such as the pattern comprising the straight line 621, the straight line 622, and the straight line 623, is disposed on the second mask 62.

The first mask 61 and the second mask 62 are stacked so that the first pattern and the second pattern can be stacked to form a third pattern, such as the pattern shown in the equivalent diagram in FIG. 7. Light emitted by the light source crosses the third pattern. In the present embodiment, the third pattern is a semiconductor pattern on an array substrate in the LCD panel. Of course, the third pattern can be a pattern during manufacturing processes of other products.

A mask defining a new pattern such as the first mask 61 and the second mask 62 is formed after the masks having the corresponding patterns are stacked. The mask is defined as a mask set. The mask set comprises a primary mask and a supplementary mask. For example, the first mask 61 is defined as the primary mask and the second mask 62 is defined as the supplementary mask. In a plurality of mask sets, at least two mask sets have the same primary masks and have different supplementary masks for reducing the number of masks.

At least one line of the corresponding pattern from a mask is located between two adjacent lines of another corresponding pattern from another mask in the new pattern. Or, at least one line of the corresponding pattern from a mask is located in the middle of two adjacent lines of another corresponding pattern from another mask in the new pattern. Or, each line of the corresponding pattern from a mask is located in the middle of two adjacent lines of another corresponding pattern from another mask in the new pattern.

The present invention adopts the method of exposing a mask set. By flexibly combining existing masks and stacking the existing masks, a desired mask pattern is obtained. Therefore, the possibility of manufacturing masks is lowered, which reduces production costs.

While the present invention has been described in connection with what is considered the most practical and preferred embodiments, it is understood that this invention is not limited to the disclosed embodiments but is intended to cover various arrangements made without departing from the scope of the broadest interpretation of the appended claims.

What is claimed is:

1. A method of photo-etching comprising:
forming a material layer on a substrate;
forming a photoresist layer on the material layer;
exposing the photoresist layer by using a stack of at least two masks, each mask defining a corresponding pattern, a new pattern being defined when the at least two masks are stacked, wherein at least one line of the corresponding pattern from one of the at least two masks is located in the middle of two adjacent lines of another corresponding pattern from another mask in the new pattern;
processing the exposed photoresist layer to derive a hollow-out structure that complements the new pattern;
etching the material layer by using the hollow-out structure to form a patterned material layer;
removing the photoresist layer of the hollow-out structure after forming the patterned material layer.

2. The method as claimed in claim 1, wherein the corresponding patterns are stacked and form a mask set defining a new pattern, the mask set comprises a primary mask and a supplementary mask, and at least two mask sets comprise the same primary mask and different supplementary masks.

3. The method as claimed in claim 1, wherein at least one line of the corresponding pattern from one of the at least two masks is located in the middle of two adjacent lines of another corresponding pattern from another mask in the new pattern.

4. The method as claimed in claim 3, wherein each line of the corresponding pattern from one of the at least two masks is located in the middle of two adjacent lines of another corresponding pattern from another mask in the new pattern.

5. A method of photo-etching comprising:
forming a material layer on a substrate;
forming a photoresist layer on the material layer;
exposing the photoresist layer by using a stack of at least two masks, each mask defining a corresponding pattern, a new pattern being defined when the at least two masks are stacked;
processing the exposed photoresist layer to derive a hollow-out structure that complements the new pattern;
etching the material layer by using the hollow-out structure to form a patterned material layer.

6. The method as claimed in claim 5, wherein the corresponding patterns are stacked and form a mask set defining a new pattern, the mask set comprises a primary mask and a supplementary mask, and at least two mask sets comprise the same primary mask and different supplementary masks.

7. The method as claimed in claim 5, wherein at least one line of the corresponding pattern from one of the at least two masks is located between two adjacent lines of another corresponding pattern from another mask in the new pattern.

8. The method as claimed in claim 7, wherein at least one line of the corresponding pattern from one of the at least two masks is located in the middle of two adjacent lines of another corresponding pattern from another mask in the new pattern.

9. The method as claimed in claim 8, wherein each line of the corresponding pattern from one of the at least two masks is located in the middle of two adjacent lines of another corresponding pattern from another mask in the new pattern.

10. The method as claimed in claim 5, further comprising removing the photoresist layer of the hollow-out structure after forming the patterned material layer.

11. An exposing system comprising:
a light source;
a first mask, defining a first pattern;
a second mask, defining a second pattern;
wherein the first mask and the second mask are stacked, the stack of the first pattern and the second pattern forms a third pattern, and light emitted by the light source crosses the third pattern.

12. The exposing system as claimed in claim 11, wherein the third pattern is a semiconductor pattern for forming an array substrate of a liquid crystal display (LCD) panel.

13. The exposing system as claimed in claim 11, wherein the corresponding patterns are stacked and form a mask set defining a new pattern, the mask set comprises a primary mask and a supplementary mask, and at least two mask sets comprise the same primary mask and different supplementary masks.

14. The exposing system as claimed in claim 11, wherein at least one line of the corresponding pattern from one of the at least two masks is located between two adjacent lines of another corresponding pattern from another mask in the new pattern.

15. The exposing system as claimed in claim 14, wherein at least one line of the corresponding pattern from one of the at least two masks is located in the middle of two adjacent lines of another corresponding pattern from another mask in the new pattern.

16. The exposing system as claimed in claim 15, wherein each line of the corresponding pattern from one of the at least two masks is located in the middle of two adjacent lines of another corresponding pattern from another mask in the new pattern.
